(19) United States
(12) Patent Application Publication
(10) Pub. No.: US 2026/0051351 A1
(43) Pub. Date: Feb. 19, 2026

(54) MEMORY CONTROLLER, STORAGE DEVICE INCLUDING THE SAME, AND OPERATING METHOD THEREOF

(71) Applicant: Samsung Electronics Co., Ltd., Suwon-si (KR)

(72) Inventors: Sangwon Kim, Suwon-si (KR); Il Han Park, Suwon-si (KR); Garam Kim, Suwon-si (KR); Jisu Kim, Suwon-si (KR); Sang-Won Park, Suwon-si (KR)

(21) Appl. No.: 19/227,202

(22) Filed: Jun. 3, 2025

(30) Foreign Application Priority Data
Aug. 16, 2024 (KR) 10-2024-0110004

(51) Int. Cl. G11C 16/10; G11C 29/00

(52) U.S. Cl. CPC G11C 16/102; G11C 29/76

(57) ABSTRACT

An operation method of a storage device comprising a memory device that includes a memory block having a plurality of strings and a memory controller configured to control the memory device, the operation method includes identifying a number of select transistors in the fail state in the memory block, based on test read information indicating that a threshold voltage state of each of a plurality of select transistors included in each of the plurality of strings is the fail state, and programming the identified select transistors according to the number of select transistors in the fail state.

### CROSS-REFERENCE TO RELATED APPLICATION(S)

This application claims the benefit of Korean Patent Application No. 10-2024-0110004, filed in the Korean Intellectual Property Office on Aug. 16, 2024, the disclosure of which is incorporated herein by reference in its entirety.

### BACKGROUND

A storage device can store data. Reliability of a storage device becomes important as the storage device is used more often. In particular, if the threshold voltage state of select transistors such as a source select transistor (SST) and a ground select transistor (GST) is a fail state, access to certain storage areas may be blocked.

### SUMMARY

In general, the present disclosure is directed toward a memory controller of which reliability is improved, a storage device including the same, and an operation method of the same.

According to some implementations, the present disclosure is directed to an operation method of a storage device including a memory device including a memory block including a plurality of strings and a memory controller configured to control the memory device, the operation method including based on test read information indicating that a threshold voltage state of each of a plurality of select transistors included in each of the plurality of strings is a fail state or a pass state, identifying a number of select transistors in the fail state in the memory block, and programming identified select transistors according to the number of select transistors in the fail state.

According to some implementations, the present disclosure is directed to a storage device including a memory device including a memory block including a plurality of strings, and a memory controller configured to control the memory device to, based on test read information indicating that a threshold voltage state of each of a plurality of select transistors included in each of the plurality of strings is a fail state or a pass state, identify a number of select transistors in the fail state in the memory block, and program identified select transistors according to the number of select transistors in the fail state.

According to some implementations, the present disclosure is directed to a memory controller configured to control a memory device including a memory block including a plurality of strings, the memory controller including a buffer memory configured to store test read information indicating that a threshold voltage state of each of a plurality of select transistors included in each of the plurality of strings is the fail state or a pass state, and a processor configured to control the memory device to identify a number of select transistors in the fail state in the memory block based on the test read information, and program identified select transistors according to the number of the select transistors in the fail state.

According to some implementations, it is possible to provide a memory controller of which reliability is improved, a storage device including the same, and an operation method of the same.

According to some implementations, it is possible to provide a memory controller that completes a reliability recovery operation in the reference time, and a storage device including the same, and an operation method of the same.

### BRIEF DESCRIPTION OF THE DRAWINGS

Example implementations will be more clearly understood from the following detailed description, taken in conjunction with the accompanying drawings.

FIG. 1 is a drawing for explaining an example of a storage device according to some implementations.

FIG. 2 is a drawing for explaining an example of a memory block according to some implementations.

FIG. 3 is a drawing for explaining an example of an operation method of a storage device according to some implementations.

FIG. 4 is a flowchart specifically explaining an example of an operation method of a storage device according to some implementations.

FIG. 5 is a drawing for explaining an example of a first method for selecting a select transistor according to priority according to some implementations.

FIG. 6 is a drawing for explaining an example of a second method for selecting a select transistor according to priority according to some implementations.

FIG. 7 is a drawing for explaining an example of a third method for selecting a select transistor according to priority according to some implementations.

FIGS. 8A to 8C are drawings for explaining an example of selecting a select transistor according to priority according to some implementations.

FIG. 9 is a diagram for explaining an example of a memory controller according to some implementations.

FIG. 10 is a drawing for explaining an example of a memory device according to some implementations.

### DETAILED DESCRIPTION

Hereinafter, example implementations will be explained in detail with reference to the accompanying drawings.

Throughout the present disclosure, when a part is described as “comprising or including” a component, it does not exclude another component but may further include another component unless otherwise stated. Furthermore, terms such as “ . . . unit,” “ . . . group,” and “ . . . module” described in the present disclosure may include one or more processors that process at least one function or operation, which may be implemented as hardware, software, or a combination thereof.

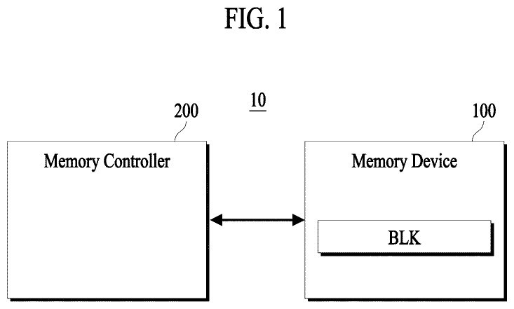

FIG. 1 is a drawing for explaining an example of a storage device according to some implementations. In FIG. 1, a storage device 10 may include a memory device 100 and a memory controller 200. The storage device 10 may be a device for storing and managing data. In some implementations, the memory device 100 and the memory controller 200 may be manufactured as separate package chips. In some implementations, the memory device 100 and the memory controller 200 may be mounted spaced apart from each other on the substrate. In some implementations, the memory device 100 and the memory controller 200 may be stacked vertically. In some implementations, the memory device 100 and the memory controller 200 may be manufactured in a form included in a single integrated package chip. In a some implementations, there may be one memory device 100 or a plurality of memory devices 100.

The memory controller 200 may control the memory device 100. For example, the memory controller 200 may send control commands to control the memory device 100 to perform specific operations, and when a control command is received, the memory device 100 may perform an operation corresponding to the control command.

Meanwhile, the memory controller 200 may communicate with an external device. The memory controller 200 may generate corresponding control commands according to requests from external devices. When a write request and data are received from an external device, the memory controller 200 may transmit program commands and data to the memory device 100, and the memory device 100 may store data. Meanwhile, when a request to read is received from an external device, the memory controller 200 may transmit a command to read to the memory device 100, and the memory device 100 may transfer the stored data to the memory controller 200. The memory controller 200 may transmit the data received from the memory device 100 to an external device.

In some implementations, the memory controller 200 may transmit program commands and data to the memory device 100, and the memory device 100 may store the data. In some implementations, the memory controller 200 may transfer program commands and data to the memory device 100, and the memory device 100 may store the data.

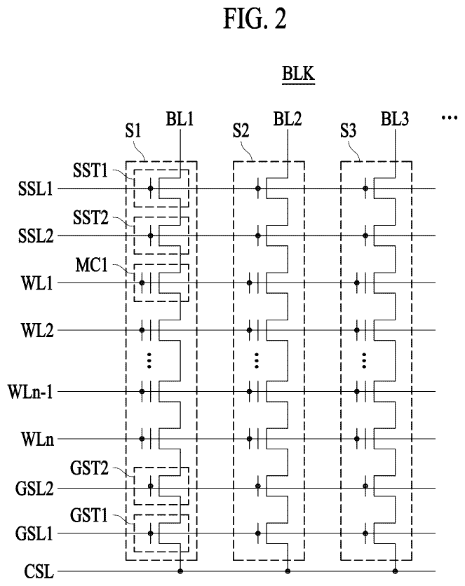

The memory device 100 may store data. The memory device 100 may include at least one memory block BLK. The memory block BLK will be specifically described with reference to FIG. 2.

FIG. 2 is a drawing for explaining an example of a memory block according to some implementations. In FIG. 2, the memory block BLK may include a plurality of strings (a first string S1 to a third string S3). In FIG. 2, the number of strings (the first string S1 to the third string S3) is depicted as three, but the number of strings may be varied and implemented in various numbers.

Each of the plurality of strings (the first string S1 to the third string S3) may include a plurality of memory cells and a plurality of select transistors. One end of each string (the first string S1 to the third string S3) may be connected to each of bitlines BL1 to BL3, and the other end of each string (the first string S1 to the third string S3) may be commonly connected to a common source line CSL. Below, the first string S1 is described in example embodiments.

In the case of a memory cell, a first memory cell MC1 is included in multiple memory cells. The first memory cell MC1 may include a semiconductor device. For example, a semiconductor device may include a floating gate transistor. For example, the floating gate transistor may include a control gate, an insulating layer, and a floating gate. The control gate of the first memory cell MC1 may be connected to the corresponding first wordline WL1. Meanwhile, the description of the first memory cell MC1 may also be applied to other memory cells.

For example, in the case of program operation, the program voltage may be applied to the control gate of the first memory cell MC1, and the program tolerant voltage may be applied to the bitline. In this case, charge may be stored in the floating gate of the first memory cell MC1 through tunneling or thermal ionization. The threshold voltage of the first memory cell MC1 may vary depending on the amount of charge stored in the floating gate. Depending on the threshold voltage of the first memory cell MC1, the first memory cell MC1 may belong to one of multiple program states. The program state may correspond to the value of the data stored in the first memory cell MC1. In some implementations, the first memory cell MC1 may store 1 bit according to a single-level cell (SLC), and the two program states of the first memory cell MC1 may correspond to either “0” or “1.” In some implementations, the first memory cell MC1 may store 2 bits according to a multi-level cell (MLC), and the four program states of the first memory cell MC1 may correspond to “00,” “01,” “10” or “11.” However, the first memory cell MC1 may store various bits of data according to various methods, such as a triple-level cell (TLC) and a quad-level cell (QLC).

For example, in the case of an erase operation, an erase voltage may be applied to the control gate of all memory cells within the memory block BLK, and a ground voltage may be applied to the substrate. In this case, charge may be removed from the floating gate of any memory cell. Every memory cell may belong to the program state (for example, an erase state) corresponding to the lowest threshold voltage among multiple program states.

Each of the plurality of select transistors may include a gate. The gate of each of the plurality of select transistors may be connected to a selection line. The select transistor may be activated or deactivated depending on the threshold voltage and the voltage applied to the gate. When the select transistor is activated, a channel is formed and current may flow. When the select transistor is deactivated, the channel may not be formed and no current may flow. For example, when the voltage applied to the gate of the select transistor is higher than the threshold voltage of the select transistor, the select transistor is activated, and when the voltage applied to the gate of the select transistor is less than the threshold voltage of the select transistor, the select transistor may be deactivated. The select transistor may function as a switch by being activated and deactivated, the switch selecting or blocking a certain memory block among a plurality of memory blocks. In some implementations, the select transistor may be implemented by being modified into a floating gate transistor.

The plurality of select transistors may include a first string select transistor SST1 and a second string select transistor SST2, and a first ground select transistor GST1 and a second ground select transistor GST2. The first string select transistor SST1 and the second string select transistor SST2 may be connected in series. The gate of each of the first string select transistor SST1 and the second string select transistor SST2 may be connected to the corresponding string selection line (a first string selection line SSL1 and a second string selection line SSL2). The first string select transistor SST1 and the second string select transistor SST2 may be placed and connected between the corresponding a first bitline BL1 and multiple memory cells. The first ground select transistor GST1 and the second ground select transistor GST2 may be connected in series. The gate of each of a plurality of ground select transistors DST1 and DST2 may be connected to a corresponding ground selection line (a first ground selection line GSL1 and a second ground selection line GSL2). The plurality of ground select transistors DST1 and DST2 may be placed and connected between the common source line CSL and multiple memory cells. In an example embodiment, the number of the string select transistors (the first string select transistor SST1 and the second string select transistor SST2) and the number of the ground select transistors (the first ground select transistor GST1 and the second ground select transistor GST2) may be varied and implemented in various ways.

In FIG. 1 and FIG. 2, the memory controller 200 may generate addresses of storage areas for performing specific operations, and transmit the addresses to the memory device 100. In some implementations, the address may include identification information for at least one of a memory block, a string, a memory cell, and a select transistor. In some implementations, the address may include identification information for at least one of a wordline, a selection line, and a bitline. The memory device 100 may perform operations on a specific storage area corresponding to an address. For example, the memory device 100 may activate all of the string select transistors (the first string select transistor SST1 and the second string select transistor SST2) and the first ground select transistor GST1 and the second ground select transistor GST2 in the memory block BLK corresponding to the address. Meanwhile, the threshold voltage of the select transistor may change depending on various factors such as an operation cycle, degradation, temperature, adjacent memory cells, and so on. For example, when the same voltage is applied to the gate in the case of the threshold voltage of the select transistor being more reduced than the reference voltage, unintended memory blocks may be selected or intended memory blocks may be not selected.

In some implementations, the memory controller 200 may control the memory device 100 to perform a test reading operation. A test reading operation may be an operation for detecting whether the threshold voltage state of each select transistor included in the memory device 100 is the pass state or the fail state. The pass state may be a state where the threshold voltage of the select transistor is higher than the reference voltage, and the fail state may be a state where the threshold voltage of the select transistor is less than the reference voltage. In some implementations, the memory controller 200 may receive and store test read information including a threshold voltage state of each of a plurality of select transistors included in the memory block BLK from the memory device 100. Meanwhile, the test read information may be transformed and implemented by being stored in the memory device 100.

For example, when the memory device 100 detects the threshold voltage state of the first string select transistor SST1 in the first string S1 of the memory block BLK, a reference voltage may be applied to the first string selection line SSL1 connected to the gate of the first string select transistor SST1, and a pass voltage may be applied to the selection line connected to the gates of the remaining select transistors in the first string S1 of the memory block BLK and a wordline connected to a memory cell within the memory block BLK. In this case, if no current is sensed through the first bitline BL1 connected to the first string S1, the first string select transistor SST1 is in the pass state, and when the current is sensed through the first bitline BL1, the first string select transistor SST1 is in the fail state. In a similar way, the memory device 100 may detect the threshold voltage state of each of other select transistors.

In some implementations, the memory controller 200 may determine the number of select transistors in the fail state within the memory block BLK based on the test read information. The memory controller 200 may control the memory device 100 to program identified (or selected) select transistors depending on the number of select transistors in the fail state. For example, the memory controller 200 may select some or all of the select transistors in the fail state depending on the number of select transistors in the fail state, and control the memory device 100 to program identified select transistors to change from the fail state to the pass state. For example, when the memory device 100 programs the first string select transistor SST1 in the fail state in the first string S1 of the memory block BLK the program voltage may be applied to the first string selection line SSL1 connected to the first string select transistor SST1, and the program tolerant voltage may be applied to the first bitline BL1 connected to the first string S1. Here, when the string select transistor connected to the first string selection line SSL1 in a string other than the first string S1 is in the pass state, the memory device 100 may apply a program inhibition voltage to the bitlines connected to other strings.

According to some implementations, by adjusting the number of recovery operations to restore select transistors in the fail state to the pass state according to the number of select transistors in the fail state, delays in other operations due to recovery operations may be minimized and the reliability of the storage device 10 may be improved. Below, more detailed example embodiments thereon are given with reference to the attached drawings.

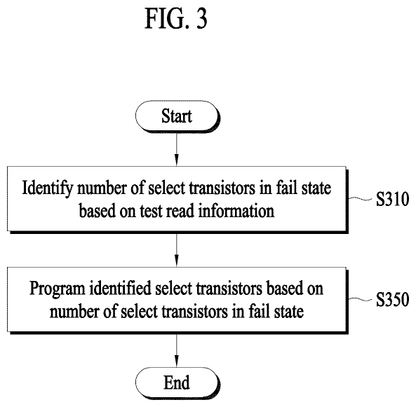

FIG. 3 is a drawing for explaining an example of an operation method of a storage device according to some implementations. In FIG. 3, the operation method of the storage device 10 may include operation S310 in which the number of select transistors in the fail state within the memory block BLK is identified based on the test read information, and operation S350 in which the identified select transistors are programmed based on the number of select transistors in the fail state.

The storage device 10 may include the memory device 100 and the memory controller 200. The test read information may be information indicating that a threshold voltage state of each of a plurality of select transistors included each of a plurality of strings is the fail state or the pass state.

In some implementations, operation S310 in which the number of select transistors in the fail state within the memory block BLK is identified based on the test read information may be performed by the memory controller 200. In a some implementations, operation S310 in which the number of select transistors in the fail state within the memory block BLK is identified based on the test read information may include identifying the number of second values among the state values corresponding to the address for the select transistor included in the memory block BLK included in the test read information.

In some implementations, operation S350 in which identified select transistors are programmed based on the number of select transistors in the fail state may be performed by the memory device 100. Operation S350 in which the identified select transistors are programed may be programmed to cause the identified select transistors to be changed from the fail state to the pass state.

In some implementations, in operation S350 in which the identified select transistors are programed, the program voltage whose voltage level sequentially increases according to the loop may be applied to the selection line connected to the gate of the identified select transistor. In other words, the memory device 100 may program the select transistor using incremental step pulse programming (ISPP).

For example, the memory device 100 may verify whether the threshold voltage of the select transistor reached the reference voltage by applying the default level program voltage to the gate of the select transistor and then applying the reference voltage to the gate of the select transistor. When the threshold voltage does not reach the reference voltage, the memory device 100 may verify whether the threshold voltage of the select transistor reached the reference voltage by applying a program voltage having a first level that is a certain level higher than the default level to the gate of the select transistor, and then applying a reference voltage to the gate of the select transistor. When the threshold voltage does not reach the reference voltage, the memory device 100 may verify whether the threshold voltage of the select transistor reached the reference voltage by applying a program voltage having a second level that is a certain level higher than the first level to the gate of the select transistor, and then applying a reference voltage to the gate of the select transistor. In a similar way, the memory device 100 may program the select transistor by repeating the program loop. Meanwhile, a maximum allowed count of the program loop may be set.

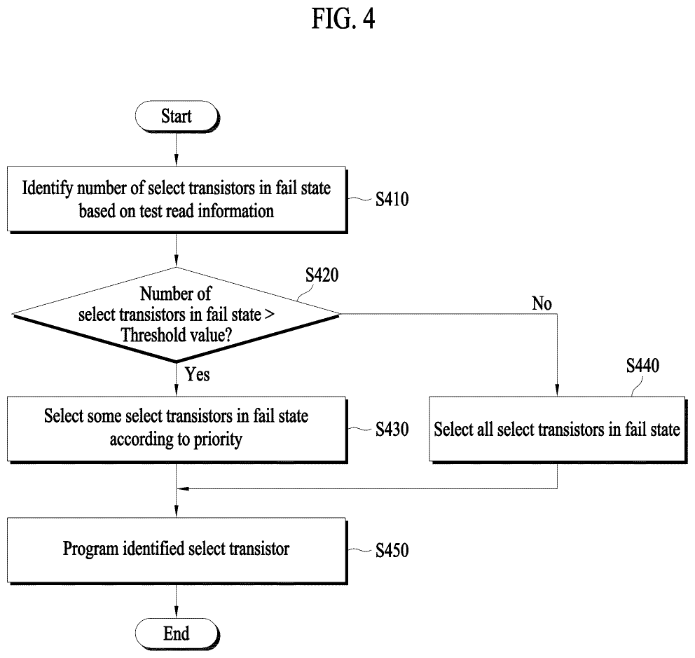

In some implementations, the operation method of the storage device 10 may further include selecting some or all of the select transistors in the fail state depending on the number of select transistors in the fail state. The selecting some or all of the select transistors in the fail state may be performed by the memory controller 200. Specific details are described with reference to FIG. 4.

FIG. 4 is a flowchart specifically explaining an example of an operation method of a storage device according to some implementations. In FIG. 4, the operation method of the storage device 10 may include operation S410 in which the number of select transistors in the fail state within the memory block BLK is identified based on the test read information, and operation S450 in which some or all of the select transistors in the fail state are identified depending on the number of select transistors in the fail state, and the identified select transistors are programed.

In some implementations, the operation method of the storage device 10 may further include operation S420 in which the number of select transistors in the fail state within the memory block BLK is compared to a threshold value. In some implementations, the threshold value may be a preset value. In some implementations, the threshold value may be a value corresponding to the reference time. For example, the threshold value may be the value obtained by dividing the reference time by the program operation time for one select transistor, with the decimal point removed. The reference time may be the maximum allowed time associated with a particular operation. In some implementations, the threshold value may be a value corresponding to the maximum allowed time (for example, tBERS) of an erase operation for a memory block. In some implementations, the threshold value may be transformed into values related to various operations, such as a value corresponding to the maximum allowed time for a reset operation, a value corresponding to the maximum allowed time for a reading operation and a value corresponding to the maximum allowed time for a program operation.

In some implementations, when the number of select transistors in the fail state is greater than the threshold value (operation S420, Yes), the operation method of the storage device 10 may further include operation S430 in which some of the select transistors in the fail state within the memory block BLK are selected as the identified select transistors according to the priority. When all of the select transistors in the fail state within the memory block BLK are selected as the identified select transistors and programmed in this case, the program operation may be completed beyond the reference time. When only some of the select transistors in the fail state within the memory block BLK are selected as the identified select transistors and programmed in this case, the program operation may be completed within the reference time.

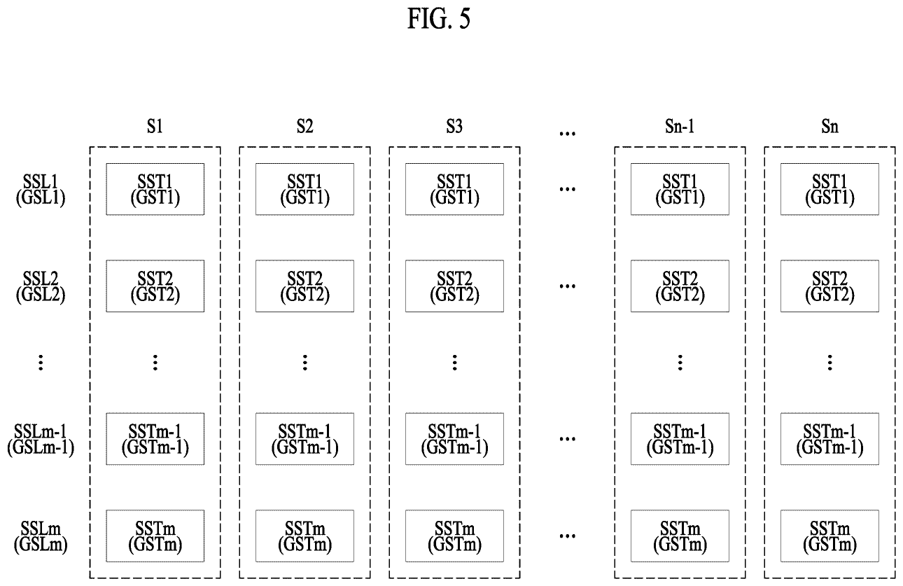

In some implementations, operation S430 in which some of the select transistors in the fail state are selected may include selecting a string whose all select transistors are in the fail state among a plurality of strings. The selecting some of the select transistors in the fail state may include selecting at least one among the select transistors in the fail state in each selected string. Detailed example embodiments thereon are described with reference to FIG. 5.

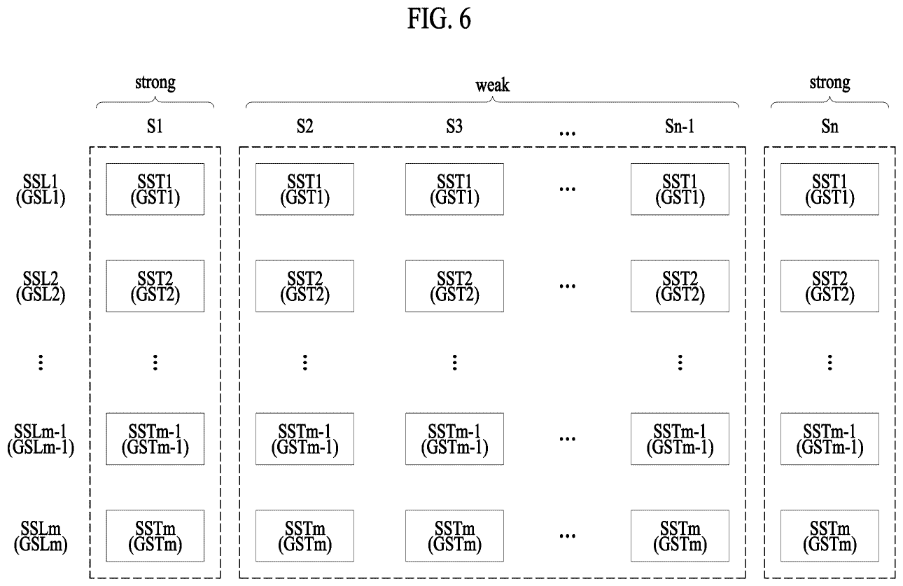

In some implementations, operation S430 in which selecting some of the select transistors in the fail state may include preferentially selecting a select transistor in the fail state included in a plurality of first strings over a select transistor in the fail state included in a plurality of second strings. Here, the plurality of first strings may be placed between other strings, and the plurality of second strings may be placed outside of the plurality of first strings. In some implementations, the preferentially selecting a select transistor in the fail state included in a plurality of first strings may include, when at least one string among the plurality of second strings has a select transistor in the pass state and a select transistor in the fail state and when the number of select transistors in the fail state included in the plurality of first strings is greater than the threshold value, selecting the number of select transistors within the threshold value or less among the select transistors in the fail state included in the plurality of first strings. Detailed example embodiments thereon are described with reference to FIG. 6.

In some implementations, the plurality of select transistors included in each of the plurality of strings may include a plurality of string select transistors and a plurality of ground select transistors connected in series, and each of the plurality of strings may include a plurality of memory cells connected in series between the plurality of string select transistors and the plurality of ground select transistors. In some implementations, the plurality of string select transistors may include an inner string select transistor and an outer string select transistor. In some implementations, the plurality of ground select transistors may include an inner ground select transistor and an outer ground select transistor.

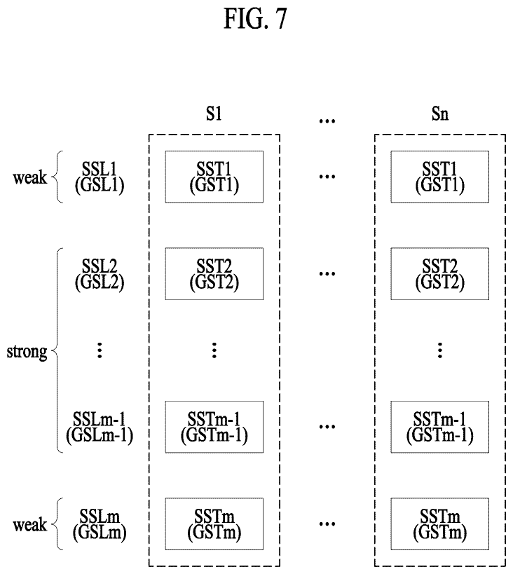

In some implementations, operation S430 in which some of the select transistors in the fail state are selected may include preferentially selecting an outer string select transistor in the fail state within a string over an inner string select transistor in the fail state. In some implementations, operation S430 in which some of the select transistors in the fail state are selected may include preferentially selecting an outer ground select transistor in the fail state within a string over an inner ground select transistor in the fail state. Detailed example embodiments thereon are described with reference to FIG. 7.

In some implementations, when the number of select transistors in the fail state is less than the threshold value (operation S420, No), the operation method of the storage device 10 may further include operation S440 in which all select transistors in the fail state in the memory block BLK are selected as the identified select transistors. In this case, when all of the select transistors in the fail state within the memory block BLK are selected as the identified select transistors and programmed, the program operation may be completed within the reference time.

In some implementations, the operation method of the storage device 10 may further include performing an erase operation on the memory block BLK before operation S410 in which the number of the select transistors are identified. For example, the memory controller 200 may control the memory device 100 to perform the erase operation on the memory block BLK. In this case, the threshold value may be the number corresponding to the maximum allowed time for the erase operation. In other words, according to the operation method of the storage device 10, the erase operation and the programming of the select transistor in the fail state may be completed within the maximum allowed time (for example, 20 ms) of the erase operation. Meanwhile, the erase operation may be changed and implemented in various ways such as re-setting or initializing the memory device 100.

In some implementations, the operation method of the storage device 10 may further include performing a test reading operation after the erase operation. The test reading operation may be performed before operation S410 in which the number of select transistors is identified. For example, the memory controller 200 may control the memory device 100 to perform a test read operation on the memory block BLK. The memory controller 200 may read the threshold voltage state of each of a plurality of select transistors within the memory block BLK and generate the test read information. In some implementations, when there is the test read information, the test reading operation may be omitted.

In some implementations, the operation method of the storage device 10 may further include updating the address for the select transistor in the fail state in the test read information after operation S450 in which the identified select transistor is programed. This is to program the remaining select transistors that are not programmed among the select transistors in the fail state when performing the next erase operation.

FIG. 5 is a drawing for explaining an example of a first method for selecting a select transistor according to priority according to some implementations. In FIG. 2 and FIG. 5, the memory block BLK of the memory device 100 may include a plurality of strings (the first string S1 to an nth string Sn). Each of the plurality of strings (the first string S1 to the nth string Sn) may include a plurality of select transistors. In some implementations, each of the plurality of strings (the first string S1 to the nth string Sn) may include a plurality of string select transistors (the first string select transistor SST1 to an mth string select transistor SSTm) and a plurality of ground select transistors (the first ground select transistor GST1 to an mth ground select transistor GSTm). Each of a plurality of string select transistors (the first string select transistor SST1 to the mth string select transistor SSTm) may be connected to multiple string selection lines (the first string selection line SSL1 to an mth string selection line SSLm), and each of a plurality of ground select transistors (the first ground select transistor GST1 to the mth ground select transistor GSTm) may be connected to multiple ground selection lines (the first ground selection line GSL1 to an mth ground selection line GSLm).

Below, where the number of select transistors in the fail state exceeds the threshold value are described. The implementations described based on the string select transistor among the select transistors (the first string select transistor SST1 to the mth string select transistor SSTm). Descriptions related thereto may be equally applied to the ground select transistors (the first ground select transistor GST1 to the mth ground select transistor GSTm).

In some implementations, the operation method of the storage device 10 may include selecting a string in which all string select transistors are in the fail state among the plurality of strings (the first string S1 to the nth string Sn) in the memory block BLK. In some implementations, when all string select transistors included in the first string S1 are in the fail state, the memory controller 200 may select the first string S1. In some implementations, when at least one of all string select transistors included in a second string S2 is not in the fail state (in other words, in the pass state), the memory controller 200 may not select the second string S2. The memory controller 200 may determine whether to select each of the other strings in the same way.

In some implementations, the operation method of the storage device 10 may include selecting at least one of the string select transistors in the fail state in each selected string. For example, the memory controller 200 may preferentially select one or more string select transistors in the fail state from the selected first string S1 as recovery targets.

In some implementations, after the program operation of changing the fail state of the string select transistor to the pass state is completed, each string (the first string S1 to the nth string Sn) may have one or more string select transistors in the pass state. It is because when at least one of all string select transistors remains in the pass state in each string, there may be a window area where a pass is possible in terms of the merged scatter for the string selection line. According to some implementations, the first method according to the above described priority may be applied with the highest priority when combined with other methods.

FIG. 6 is a drawing for explaining an example of a second method for selecting a select transistor according to priority according to some implementations. In FIG. 2 and FIG. 6, the memory block BLK of the memory device 100 may include the plurality of strings (the first string S1 to the nth string Sn). Each of the plurality of strings (the first string S1 to the nth string Sn) may include a plurality of select transistors. In some implementations, each of the plurality of strings (the first string S1 to the nth string Sn) may include the plurality of string select transistors (the first string select transistor SST1 to the mth string select transistor SSTm) and the plurality of ground select transistors (the first ground select transistor GST1 to the mth ground select transistor GSTm). Each of the plurality of string select transistors (the first string select transistor SST1 to the mth string select transistor SSTm) may be connected to multiple string selection lines (the first string selection line SSL1 to the mth string selection line SSLm), and each of the plurality of ground select transistors (the first ground select transistor GST1 to the mth ground select transistor GSTm) may be connected to multiple ground selection lines (the first ground selection line GSL1 to the mth ground selection line GSLm).

The plurality of strings (the first string S1 to the nth string Sn) may include the plurality of weak strings and the plurality of strong strings. For weak strings, reliability may be more vulnerable than the strong strings. For example, the weak strings and the strong strings may be distinguished based on various factors such as positional relationship, interference of surrounding strings, charge loss, retention characteristics and a hole contact/drain and cut area. In an example embodiment, the plurality of weak strings are placed on the inside, and the plurality of strong strings are placed outside the plurality of weak strings. In some implementations, the plurality of weak strings are placed between other strings.

Below described are some implementations where the number of select transistors in the fail state exceeds the threshold value. The implementations are described based on the string select transistors (the first string select transistor SST1 to the mth string select transistor SSTm) among the select transistors. The related explanation may be equally applied to the ground select transistors (the first ground select transistor GST1 to the mth ground select transistor GSTm).

In some implementations, the operation method of the storage device 10 may include preferentially selecting a string select transistor in the fail state included in the plurality of weak strings over a string select transistor in the fail state included in the plurality of strong strings. For example, the plurality of weak strings may include the second string S2 to an n−1 string Sn−1, and the plurality of strong strings may include the first string S1 and an nth string Sn which are arranged outside the second string S2 to the n−1 string Sn−1.

In some implementations, the operation method of the storage device 10 may include preferentially selecting a string select transistor that is in the fail state included in the plurality of weak strings when there is at least one string select transistor in the pass state in each of the plurality of strong strings. For example, there may be one or more string select transistors in the pass state in each of the first string S1 and the nth string Sn, and there may be a string select transistor in the fail state in at least one of the first string S1 and the nth string Sn. In this case, the memory controller 200 may preferentially select a string select transistor that is in the fail state included in the plurality of weak strings. In some implementations, when the number of string select transistors in the fail state included in the plurality of weak strings is greater than the threshold value, the memory controller 200 may select string select transistors of a threshold value number or less among the string select transistors in the fail state included in the plurality of weak strings.

In some implementations, the operation method of the storage device 10 may include preferentially selecting one of the string select transistors in the fail state in a strong string where there is no string select transistor in the pass state when there is no string select transistor in the pass state among the plurality of string strings. For example, when all string select transistors included in any one of the plurality of strong strings are in the fail state, the memory controller 200 may preferentially select one of the string select transistors in the fail state in the corresponding strong string. After then, the memory controller 200 may preferentially select a string select transistor that is in the fail state among the plurality of weak strings over other string select transistors. In other words, the priority described in FIG. 5 may be applied as the first priority, and the priority described in FIG. 6 may be applied as the second priority.

FIG. 7 is a drawing for explaining an example of a third method for selecting a select transistor according to priority according to some implementations. In FIG. 2 and FIG. 7, the memory block BLK of the memory device 100 may include the plurality of strings (the first string S1 to the nth string Sn). Each of the plurality of strings (the first string S1 to the nth string Sn) may include a plurality of select transistors. In some implementations, each of the plurality of strings (the first string S1 to the nth string Sn) may include the plurality of string select transistors (the first string select transistor SST1 to the mth string select transistor SSTm) and the plurality of ground select transistors (the first ground select transistor GST1 to the mth ground select transistor GSTm). Each of the plurality of string select transistors (the first string select transistor SST1 to the mth string select transistor SSTm) may be connected to the multiple string selection lines (the first string selection line SSL1 to the mth string selection line SSLm), and each of the plurality of ground select transistors (the first ground select transistor GST1 to the mth ground select transistor GSTm) may be connected to the multiple ground selection lines (the first ground selection line GSL1 to the mth ground selection line GSLm).

The plurality of string select transistors (the first string select transistor SST1 to the mth string select transistor SSTm) may include an inner string select transistor and an outer string select transistor. The inner string select transistor may be placed between the outer string select transistors. The outer string select transistor may include a first outer string select transistor connected to a bitline and a second outer string select transistor connected to a memory cell. For example, the first outer string select transistor may be the first string select transistor SST1 and the second outer string select transistor may be the mth string select transistor SSTm. The inner string select transistor may include the second string select transistor SST2 to an m−1th string select transistor SSTm−1.

The plurality of ground select transistors (the first ground select transistor GST1 to the mth ground select transistor GSTm) may include an inner ground select transistor and an outer ground select transistor. The inner ground select transistor may be placed between the outer ground select transistors. The outer ground select transistor may include a first outer ground select transistor connected to a common source line and a second outer ground select transistor connected to a memory cell. For example, the first outer ground select transistor may be the first ground select transistor GST1, and the second outer ground select transistor may be the mth ground select transistor GSTm. The inner ground select transistor may include the second ground select transistor GST2 to an m−1th ground select transistors GSTm−1.

Below, some implementations where the number of select transistors in the fail state exceeds the threshold value are described. Some implementations are described based on the string select transistors (the first string select transistor SST1 to the mth string select transistor SSTm) among the select transistors. The related explanation may be equally applied to the ground select transistors (the first ground select transistor GST1 to the mth ground select transistor GSTm).

In some implementations, the operation method of the storage device 10 may include preferentially selecting an outer string select transistor in the fail state within the string over an inner string select transistor in the fail state. Here, in the case of the outer string select transistor, reliability may be more vulnerable than reliability of inner string select transistors. For example, when all string select transistors within the first string S1 are in the fail state, the memory controller 200 may preferentially select the outer string select transistor over the inner string select transistor in the first string S1. Here, the outer string select transistor may include the first string select transistor SST1 and the mth string select transistor SSTm, and the inner string select transistor may include the second string select transistor SST2 to the m−1th string select transistor SSTm−1.

In some implementations, the operation method of the storage device 10 may include preferentially selecting the first outer string select transistor in the fail state within a string over the second outer string select transistor in the fail state. For example, when all string select transistors within the first string S1 are in the fail state, the memory controller 200 may preferentially select the first outer string select transistor connected to a bitline in the first string S1 over the second outer string select transistor connected to a memory cell. Here, the first outer string select transistor may be the first string select transistor SST1, and the second outer string select transistor may be the mth string select transistor SSTm.

In some implementations, the operation method of the storage device 10 may include preferentially selecting the second outer string select transistor in the fail state within a single string over the first outer string select transistor in the fail state. For example, when all string select transistors within the first string S1 are in the fail state, the memory controller 200 may preferentially select the second outer string select transistor connected to the memory cell in the first string S1 over the first outer string select transistor connected to the bitline.

In some implementations, the operation method of the storage device 10 may include selecting string select transistors in the order of string select transistors from those closest to the memory cell to those farther away in one string. For example, string select transistors may be identified in the order of the first string select transistor SST1, the second string select transistor SST2, . . . , the mth string select transistor SSTm.

In some implementations, the operation method of the storage device 10 may include selecting string select transistors in the order of increasing distance from the string select transistor closest to the memory cell within a string. For example, select transistors may be identified in the order of the mth string select transistor SSTm, an m−1th string select transistor SSTm−1, . . . , the first string select transistor SST1.

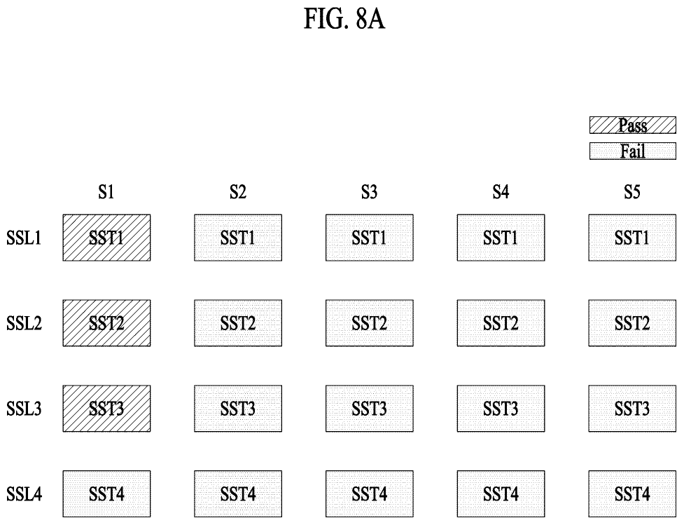

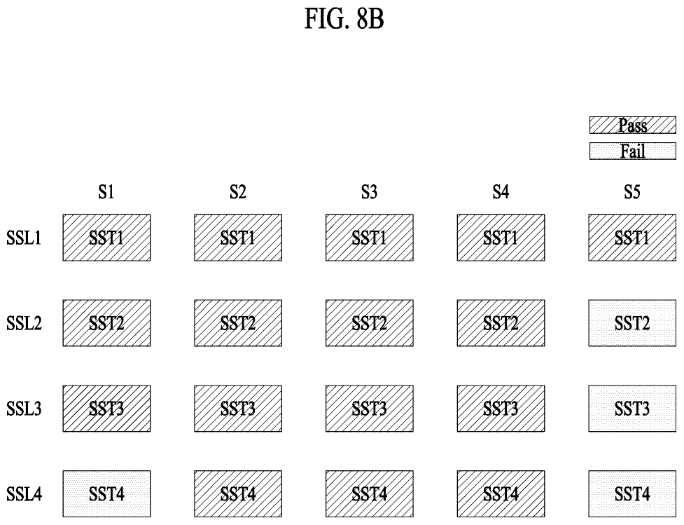

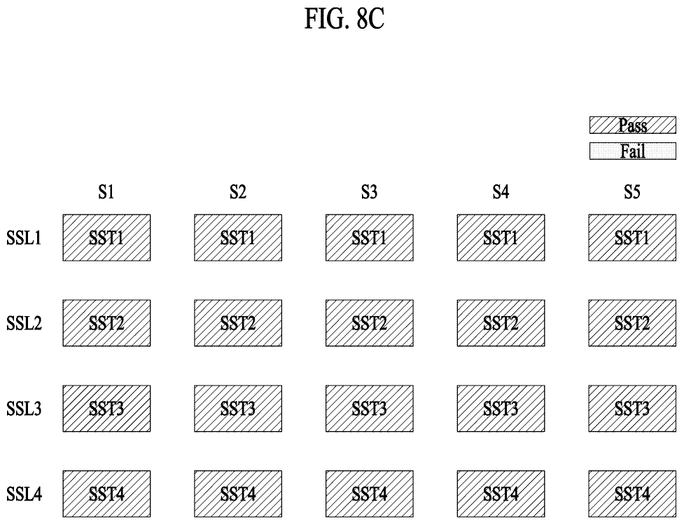

FIGS. 8A to 8C are drawings for explaining an example of selecting a select transistor according to priority according to some implementations, in which FIGS. 8A to 8C illustrate sequential selection of select transistors. In FIG. 8A and FIG. 8C, the memory block BLK of the memory device 100 may include a plurality of strings (the first string S1 to the fifth string S5). Each of the plurality of strings (the first string S1 to the fifth string S5) may include a plurality of select transistors. In an example embodiment, each of the plurality of strings (the first string S1 to the fifth string S5) may include a plurality of string select transistors (the first string select transistor SST1 to a fourth string select transistor SST4). Each of the plurality of string select transistors (the first string select transistor SST1 to the fourth string select transistor SST4) may be connected to multiple string selection lines (the first string selection line SSL1 to a fourth string selection line SSL4).

Each of the plurality of string select transistors (the first string select transistor SST1 to the fourth string select transistor SST4) may have a threshold voltage state of either the fail state or the pass state. The plurality of string select transistors (the first string select transistor SST1 to the fourth string select transistor SST4) may include an inner string select transistor and an outer string select transistor. The inner string select transistors may include the second string select transistor SST2 and a third string select transistor SST3, and the outer string select transistors may include the first string select transistor SST1 and the fourth string select transistor SST4.

The plurality of strings (the first string S1 to the fifth string S5) may include the plurality of weak strings and the plurality of strong strings. The plurality of weak strings may include the second string S2 to a fourth string S4, and the plurality of strong strings may include the first string S1 and the fifth string S5.

In FIG. 8A, the operation method of the storage device 10 may include identifying the threshold voltage state of the string select transistor based on the test read information after a specific operation. Here, the specific operation may be the erase operation, but is not limited thereto, and the specific operation may be transformed in various operations. The test read information may be pre-saved, or may be generated by performing a test reading operation after the erase operation.

In the operation method of the storage device 10, the number of string select transistors in the fail state may be identified, and the number of string select transistors in the fail state may be compared to a threshold value. For example, the number of string select transistors in the fail state may be 17, and the threshold value may be 13.

In the operation method of the storage device 10, when the number of string select transistors in the fail state is greater than the threshold value, a string may be selected of which all string select transistors are in the fail state. For example, selected strings may be the second string S2 to the fifth string S5.

The operation method of the storage device 10 may include selecting at least one string select transistor in the fail state among each selected string. Here, the operation method of the storage device 10 may include preferentially selecting the outer string select transistor over the inner string select transistor. Further, the operation method of the storage device 10 may include preferentially selecting the first outer string select transistor connected to the bitline over the second outer string select transistor. For example, in each of the second string S2 to the fifth string S5, the first string select transistor SST1, which is the first outer string select transistor, may be selected.

Further, the operation method of the storage device 10 may include preferentially selecting a string select transistor in the fail state included in a plurality of weak strings over a string select transistor in the fail state included in the plurality of strong strings. For example, the second string select transistor SST2 to the fourth string select transistor SST4 may be selected preferentially over the second string select transistor SST2 to the fourth string select transistor SST4 of the fifth string and the fourth string select transistor SS4 of the first string. The operation method of the storage device 10 may include programing the selected string select transistors. FIG. 8B illustrates that the selected string select transistors of the number according to the threshold value are programmed from the state in FIG. 8A.

In the operation method of the storage device 10 may include updating the remaining string select transistors to the test read information. For example, updating the remaining string select transistors may include the second string select transistor SST2 to the fourth string select transistor SST4 of the fifth string and the fourth string select transistor SS4 of the first string.

In FIG. 8B, after performing the next operation, the operation method of the storage device 10 may include identifying the threshold voltage state of the string select transistor based on the updated test read information. Here, the next operation may be the erase operation.

In the operation method of the storage device 10, the number of string select transistors in the fail state may be identified, and the number of string select transistors in the fail state may be compared to a threshold value. For example, the number of string select transistors in the fail state may be 4, and the threshold value may be 13.

In the operation method of the storage device 10, when the number of string select transistors in the fail state is less than the threshold value, all string select transistors in the fail state may be selected. For example, the selected strings may include the second string select transistor SST2 to the fourth string select transistor SST4 of the fifth string, and the fourth string select transistor SS4 of the first string. In the operation method of the storage device 10, the selected string select transistors may be programed. FIG. 8C illustrates that the selected string select transistors of the number of the threshold value or less are programed from the state of FIG. 8B. In the operation method of the storage device 10, the remaining string select transistors may be updated with the test read information. In this case, the remaining string select transistors may not exist.

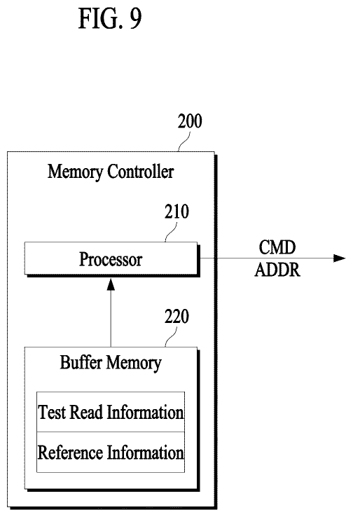

FIG. 9 is a diagram for explaining an example of a memory controller according to some implementations. In FIG. 9, the memory controller 200 may include a processor 210 and a buffer memory 220.

The processor 210 may control the overall operation of the memory controller 200. The processor 210 may execute programs or compute (or process) data. For example, the processor 210 may include at least one of a central processing unit (CPU), a digital signal processor (DSP), an application processing unit (APU), and a system on chip (SoC).

The buffer memory 220 may store data. In some implementations, the buffer memory 220 may include various volatile memories, such as dynamic random access memory (DRAM), static RAM (SRAM), and synchronous DRAM (SDRAM). In some implementations, the buffer memory 220 may include non-volatile memory.

In some implementations, the buffer memory 220 may store the test read information. The test read information may indicate that a threshold voltage state of each select transistor included in each of the plurality of strings in the memory block BLK is either the fail state or the pass state. For example, the test read information may include an address and a state value for each of a plurality of select transistors. The state value may be either a first value or a second value. The first value may represent the pass state, and the second value may represent the fail state. In some implementations, the test read information may be received and stored in the memory device 100. In some implementations, the test read information may be updated by the processor 210.

In some implementations, the processor 210 may identify the number of select transistors in the fail state within a memory block based on the test read information. For example, the processor 210 may identify the number of second values among state values corresponding to an address for select transistors included in the memory block BLK included in the test read information.

In some implementations, the processor 210 may control the memory device 100 to program identified select transistors based on the number of select transistors in the fail state. For example, the processor 210 may select some or all of the select transistors depending on the number of select transistors in the fail state.

In some implementations, the processor 210 may control the memory device 100 to perform the erase operation on the memory block BLK. For example, the processor 210 may transmit a command CMD for an erase operation and an address ADDR corresponding to the memory block BLK to the memory device 100. In response to the received command CMD and the address ADDR, the memory device 100 may perform an erase operation on the memory block BLK. After then, the processor 210 may identify the number of select transistors in the fail state within a memory block based on the test read information, and the processor 210 may control the memory device 100 to program identified select transistors based on the number of select transistors in the fail state. Here, the erase operation and the operation of programming the select transistor may be performed and completed within the maximum allowed time of the erase operation corresponding to the threshold value.

In some implementations, when the number of select transistors in the fail state is greater than the threshold value, the processor 210 may select some of the select transistors in the fail state within the memory block BLK. To the memory device 100, the processor 210 may transmit the command CMD for a program operation to program the identified select transistor of the memory device 100, and the address ADDR for the identified select transistor.

In some implementations, when the number of select transistors in the fail state is less than the threshold value, the processor 210 may select all select transistors in the fail state within the memory block BLK. To the memory device 100, the processor 210 may transmit the command CMD for the program operation to program the select transistor of the memory device 100, and the address ADDR for the identified select transistor.

Hereinafter, described are example implementations in which some select transistors are identified according to the priority when the number of select transistors are greater than a threshold value.

In some implementations, among a plurality of strings the processor 210 may select a string in which all select transistors within it are in the fail state. The processor 210 may select at least one of the select transistors in the fail state for each selected string.

In some implementations, the processor 210 may select select transistors in the fail state included in the plurality of weak strings over select transistors in the fail state included in the plurality of strong strings. Here, a weak string may be placed between other strings, and a strong string may be placed on only one side of another string.

In some implementations, the processor 210 may preferentially select an outer string select transistor in the fail state within a string over an inner string select transistor in the fail state. The inner string select transistor may be connected between the outer string select transistors. In some implementations, the processor 210 may preferentially select an outer ground select transistor in the fail state over an inner ground select transistor in the fail state within a string. The inner ground select transistor may be connected between the outer ground select transistors.

In some implementations, the processor 210 may preferentially select the first outer string select transistor in the fail state within a string over the second outer string select transistor in the fail state. The first outer string select transistor may be connected to a bitline, and the second outer string select transistor may be connected to a memory cell. In some implementations, the processor 210 may preferentially select a first outer ground select transistor in the fail state within a string over a second outer ground select transistor in the fail state. The first outer ground select transistor may be connected to a common source line, and the second outer ground select transistor may be connected to a memory cell.

In some implementations, the processor 210 may preferentially select a second outer string select transistor in the fail state within a string over a first outer string select transistor in the fail state. In some implementations, the processor 210 may preferentially select a second outer ground select transistor in the fail state within a string over a first outer ground select transistor in the fail state.

In some implementations, the processor 210 may select string select transistors in the order of string select transistors from those farther from the memory cell to those closer within one string. In some implementations, the processor 210 may select string select transistors in the order from the string select transistor closest to the memory cell to the string select transistor farther away within one string.

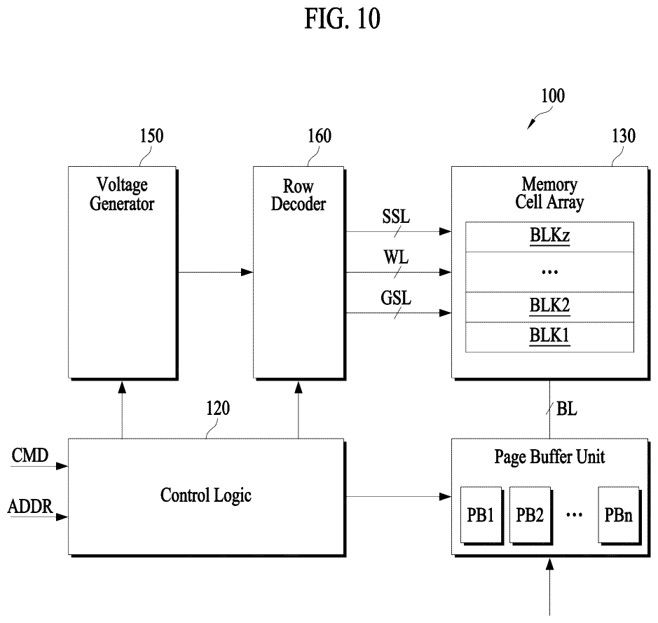

FIG. 10 is a drawing for explaining an example of a memory device according to some implementations. In FIG. 10, the memory device 100 may include at least one of control logic 120, a memory cell array 130, a page buffer unit 140, a voltage generator 150 and a row decoder 160.

The control logic 120 may control the overall operation of various operations within the memory device 100. The control logic 120 may output various control signals in response to the command CMD and the address ADDR received from the memory controller 200. For example, the control logic 120 may output a voltage control signal for performing an operation according to the command CMD, a row address corresponding to the address ADDR, and a column address.

The memory cell array 130 may include a plurality of memory blocks BLK1 to BLKz. Each of the plurality of memory blocks BLK1 to BLKz may include a plurality of strings, and each of the plurality of strings may include a plurality of memory cells and a plurality of select transistors. The memory cell array 130 may be connected to the page buffer unit 140 via the bitline BL. The memory cell array 130 may be connected to the row decoder 160 via the wordline WL, a string selection line SSL and the ground selection line GSL. In some implementations, each string of the memory cell array 130 may include memory cells each connected to a plurality of wordlines stacked vertically on the substrate. Each string may include a select transistor each connected to a selection line stacked vertically on the substrate.

The page buffer unit 140 may include a plurality of page buffers PB1 to PBn. Each of the plurality of page buffers PB1 to PBn may be connected to a string through the corresponding bitline BL. The page buffer unit 140 may select at least one bitline from the bitlines BL in response to a column address. The page buffer unit 140 may operate as a write driver or a sense amplifier, depending on its operation. For example, during the program operation, the page buffer unit 140 may apply a program permission voltage or a program inhibition voltage to a identified bitline. In the reading operation (or the test reading operation), the page buffer unit 140 may detect the data or the threshold voltage state of the string by detecting the current or the voltage of the identified bitline.

The voltage generator 150 may generate various types of voltage for performing a program operation, a reading operation and an erase operation based on a voltage control signal. For example, the voltage generator 150 may generate the program voltage, the read voltage, the program verifying voltage, the erase voltage, the pass voltage and so on to be applied to the wordline voltage and selection line.

The row decoder 160 may select at least one of a plurality of wordlines and a plurality of selection lines in response to a row address.

The electronic device according to the above-described example implementations may include a processor, a memory for storing and executing program data, a permanent storage such as a disk drive, and/or a user interface device such as a communication port, a touch panel, a key and/or a button that communicates with an external device. Methods implemented as software modules or algorithms may be stored in a computer-readable recording medium as computer-readable codes or program instructions executable on the processor. Here, the computer-readable recording medium includes a magnetic storage medium (for example, ROMs, RAMs, floppy disks and hard disks) and an optically readable medium (for example, CD-ROMs and DVDs). The computer-readable recording medium may be distributed among network-connected computer systems, so that the computer-readable codes may be stored and executed in a distributed manner. The medium may be readable by a computer, stored in a memory, and executed on a processer.

The example implementations may be represented by functional block elements and various processing steps. The functional blocks may be implemented in any number of hardware and/or software configurations that perform specific functions. For example, an example embodiment may adopt integrated circuit configurations, such as memory, processing, logic and/or look-up table, that may execute various functions by the control of one or more microprocessors or other control devices. Similar to that elements may be implemented as software programming or software elements, the example implementations may be implemented in a programming or scripting language such as C, C++, Java, assembler, etc., including various algorithms implemented as a combination of data structures, processes, routines, or other programming constructs. Functional aspects may be implemented in an algorithm running on one or more processors. Further, the example implementations may adopt the existing art for electronic environment setting, signal processing, and/or data processing. Terms such as “mechanism,” “element,” “means” and “configuration” may be used broadly and are not limited to mechanical and physical elements. The terms may include the meaning of a series of routines of software in association with a processor or the like.

While this disclosure contains many specific implementation details, these should not be construed as limitations on the scope of what may be claimed, equivalents thereof, as well as claims to be described later. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. An operation method of a storage device, wherein the storage device comprises a memory device and a memory controller, the memory device including a memory block that includes a plurality of strings, and the memory controller being configured to control the memory device,
the operation method comprising:
identifying a number of select transistors in a fail state in the memory block, based on test read information indicating that a threshold voltage state of each of a plurality of select transistors included in each of the plurality of strings is the fail state; and
programming the identified select transistors according to the number of select transistors in the fail state.

2. The operation method of the storage device of claim 1, further comprising, based on the number of select transistors in the fail state being greater than a threshold value, selecting, as the identified select transistors, at least two or more select transistors among the select transistors that are in the fail state in the memory block.

3. The operation method of the storage device of claim 2, further comprising, based on the number of select transistors in the fail state being less than or equal to the threshold value, selecting, as the identified select transistors, all of the select transistors that are in the fail state in the memory block.

4. The operation method of the storage device of claim 2, wherein selecting at least two or more select transistors among the select transistors that are in the fail state comprises:
selecting a string of select transistors among the plurality of strings that are in the fail state; and
selecting at least one select transistor among the string of select transistors in the fail state.

5. The operation method of the storage device of claim 2,
wherein the plurality of strings comprise a plurality of first strings and a plurality of second strings outside of the plurality of first strings, and
wherein selecting at least two or more select transistors among the select transistors that are in the fail state comprises selecting the two or more select transistors in the fail state included in the plurality of first strings over a select transistor in the fail state included in the plurality of second strings.

6. The operation method of the storage device of claim 5, wherein selecting a select transistor in the fail state included in the plurality of first strings over a select transistor in the fail state included in the plurality of second strings comprises:
based on at least one select transistor in a pass state being present in each of the plurality of second strings, and based on a number of select transistors in the fail state included in the plurality of first strings being greater than the threshold value, selecting, as the identified select transistors, select transistors having a number of the threshold value or less among the select transistors in the fail state included in the plurality of first strings.

7. The operation method of the storage device of claim 2,
wherein the plurality of select transistors included in each of the plurality of strings comprise (i) a plurality of string select transistors that are connected in series and (ii) a plurality of ground select transistors, and
wherein each of the plurality of strings comprises a plurality of memory cells connected in series between the plurality of string select transistors and the plurality of ground select transistors.

8. The operation method of the storage device of claim 7,
wherein the plurality of string select transistors comprise at least one inner string select transistor and at least one outer string select transistor, and
wherein selecting at least two or more select transistors among the select transistors in the fail state comprises selecting an outer string select transistor in the fail state over an inner string select transistor in the fail state within a same string.

9. The operation method of the storage device of claim 7,
wherein the plurality of ground select transistors comprise at least one inner ground select transistor and at least one outer ground select transistor, and
wherein selecting at least two or more select transistors among the select transistors in the fail state comprises selecting an outer ground select transistor in the fail state over an inner ground select transistor in the fail state in a same string.

10. The operation method of the storage device of claim 2, further comprising performing an erase operation on the memory block before identifying the number of select transistors, and
wherein the threshold value is a number corresponding to a maximum allowed time for the erase operation.

11. The operation method of the storage device of claim 10, further comprising, after performing the erase operation, performing a test reading operation to generate the test read information by reading a threshold voltage state of each of the plurality of select transistors.

12. The operation method of the storage device of claim 10, further comprising, after programming the identified select transistors, updating the test read information with an address for the select transistors in the fail state.

13. The operation method of the storage device of claim 1, wherein programming the identified select transistors comprises applying a program voltage to a selection line connected to a gate of each of the identified select transistors, the program voltage being configured to increase according to a loop.

14. A storage device comprising:
a memory device comprising a memory block that includes a plurality of strings; and
a memory controller configured to control the memory device to:
identify a number of select transistors in a fail state in the memory block, based on test read information indicating that a threshold voltage state of each of a plurality of select transistors included in each of the plurality of strings is the fail state; and
program the identified select transistors according to the number of select transistors in the fail state.

15. The storage device of claim 14, wherein the memory controller is configured to:
select at least two or more select transistors among the select transistors in the fail state in the memory block, based on the number of select transistors in the fail state being greater than a threshold value; and
transmit, to the memory device, a program command instructing the memory device to program the select transistors in the fail state and a first address for the select transistors in the fail state.

16. The storage device of claim 15, wherein the memory controller is configured to:
select a string of select transistors among the plurality of strings that are in the fail state; and
select at least one select transistor among the string of select transistors in the fail state.

17. The storage device of claim 15,
wherein the plurality of strings comprise a plurality of first strings and a plurality of second strings outside of the plurality of first strings, and
wherein the memory controller is configured to select a select transistor among the select transistors that are in the fail state included in the plurality of first strings over a select transistor in the fail state included in the plurality of second strings.

18. The storage device of claim 15,
wherein the memory controller is configured to control the memory device to perform an erase operation on the memory block, and
wherein the erase operation is performed within a maximum allowed time of the erase operation corresponding to the threshold value.

19. The storage device of claim 14, wherein the memory controller is configured to:
select the select transistors in the fail state in the memory block, based on the number of select transistors in the fail state being less than or equal to a threshold value; and
transmit, to the memory device, a program command instructing the memory device to program the select transistors in the fail state and a second address for the select transistors in the fail state.

20. A memory controller configured to control a memory device comprising a memory block that includes a plurality of strings, the memory controller comprising:
a buffer memory configured to store test read information indicating that a threshold voltage state of each of a plurality of select transistors included in each of the plurality of strings is a fail state or a pass state; and
a processor configured to control the memory device to identify a number of select transistors in the fail state in the memory block based on the test read information, and program the identified select transistors according to the number of select transistors in the fail state.
